(19) United States
(12) Patent Application Publication
(10) Pub. No.: US 2026/0156969 A1
(43) Pub. Date: Jun. 4, 2026

(54) DIODES WITH IMPROVED STRUCTURE AND PERFORMANCE

(71) Applicant: GOOGLE LLC, Mountain View, CA (US)

(72) Inventors: Aurelien Jean Francois David, San Francisco, CA (US); Miao-Chan Tsai, Sunnyvale, CA (US); Benjamin Leung, Sunnyvale, CA (US); Syed Ahmed AI Muyeed, San Ramon, CA (US); Richard Peter Schneider, JR., Mountain View, CA (US); Hasti Majidi, San Jose, CA (US); Sheila K. Hurtt, Palo Alto, CA (US); Gang He, Cupertino, CA (US); Chih Wei Chuang, Albany, CA (US)

(21) Appl. No.: 18/968,675

(22) Filed: Dec. 4, 2024

(51) Int. Cl. H10H 20/812; H10H 29/01; H10H 29/14; H10H 29/39; H10H 29/85

(52) U.S. Cl. CPC H10H 20/812; H10H 29/012; H10H 29/142; H10H 29/39; H10H 29/8517

(57) ABSTRACT

In a general aspect, a light-emitting diode (LED) includes a plurality of indium-gallium-nitride (InGaN) quantum wells (QWs). The plurality of InGaN QWs include respective light-emitting indium-containing layers having an indium concentration of less than 30%. The LED further includes a plurality of quantum barriers respectively disposed between the plurality of InGaN QWs. The plurality of quantum barriers include respective aluminum-containing layers. The LED, during electrical operation, is configured to emit light at a peak wavelength greater than 610 nanometers (nm) at a current density greater than or equal to 1 amp-per-centimeter-squared (A/cm2).

### TECHNICAL FIELD

This description relates to emissive display devices and light emitters included in such displays.

### SUMMARY

In a general aspect, a light-emitting diode (LED) includes a plurality of indium-gallium-nitride (InGaN) quantum wells (QWs). The plurality of InGaN QWs include respective light-emitting indium-containing layers having an indium concentration of less than 30%. The LED further includes a plurality of quantum barriers respectively disposed between the plurality of InGaN QWs. The plurality of quantum barriers include respective aluminum-containing layers. The LED, during electrical operation, is configured to emit light at a peak wavelength greater than 610 nanometers (nm) at a current density greater than or equal to 1 amp-per-centimeter-squared.

In another general aspect, a display includes a plurality of pixels. A pixel of the plurality of pixels includes a red light-emitting diode (LED) having a plurality of indium-gallium-nitride-containing (InGaN-containing) red quantum wells (QWs) that are respectively separated by aluminum-containing quantum barriers. The display further includes a green LED having a plurality of InGaN-containing green QWs, and a blue LED having a plurality of InGaN-containing blue QWs. The display is configured, during electrical operation, to emit white light with a brightness greater than 1 million nits, with the red LED having a peak wavelength of greater than or equal to 600 nanometers (nm).

In another general aspect, a method of operating a display includes emitting white light having a brightness greater than or equal to one-million nits. The method includes respectively driving a plurality of red light-emitting diodes (LEDs) of pixels of the display with a first current density to emit red light with a peak wavelength of greater than or equal to 600 nanometers (nm). The plurality of red LEDs including respective pluralities of indium-gallium-nitride-containing (InGaN-containing) red quantum wells (QWs) that are separated by quantum barriers containing aluminum. The method further includes respectively driving a plurality of green LEDs of the pixels with a second current density to emit green light, and respectively driving a plurality of blue LEDs of the pixels with a third current density to emit blue light.

### BRIEF DESCRIPTION OF THE DRAWINGS

FIG. 1 is a diagram schematically illustrating an example light-emitting diode (LED) with aluminum-containing barriers.

FIG. 2 is a graph illustrating a comparison of emission wavelength as a function of current density for an LED including aluminum-containing barriers with a prior LED implementation.

FIG. 3 is a graph illustrating a comparison of internal quantum efficiency (IQE) for an LED including aluminum-containing barriers with a prior LED implementation.

FIGS. 4A to 4E are diagrams schematically illustrating example active region periods for various LEDs.

FIG. 5 is a graph illustrating a comparison of peak emission wavelength for LEDs with aluminum-containing barriers with different aluminum percentage content.

FIG. 6 is a diagram schematically illustrating an example display system.

FIG. 7 is a flowchart illustrating an example method of operating an LED.

FIG. 8 is a flowchart illustrating an example method of operating a display.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in the same view, or in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated in a given view.

### DETAILED DESCRIPTION

Display devices or display systems can include a display panel, such as an emissive display panel, which can include emissive elements. The emissive elements can include light-emitting didoes (LEDs), microLEDs, and/or other light-emitting devices. For purposes of this disclosure, emissive elements of a display panel, display device, and/or display system (collectively “display”) are described as LEDs or microLEDs, where microLEDs can have lateral dimensions on the order of tens of micrometers or less. In a display, emissive elements of different colors (e.g., red, green, and blue) can be arranged in pixels that are configured to emit light of colors across the visible spectrum. In some implementations, the LEDs of pixels are implemented using III-Nitride materials, such as LEDs with indium-gallium-nitride (InGaN) active regions, e.g., InGaN quantum wells (QWs). In some applications, such as displays included in wearable devices (e.g., augmented-reality glasses, smart watches, etc.), brightness and/or color requirements can be difficult to achieve, e.g., for white light emission.

At least one technical problem with prior implementations, is achieving light emission with a sufficiently long wavelength for red light emission, e.g., of red III-Nitride LEDs of pixels, with an internal-quantum efficiency (IQE) of the red LEDs that is sufficient to facilitate achieving brightness levels for some applications, such as those noted above. That is, a technical problem with prior implementations is achieving red light emission with a wavelength of 600 nanometers (nm) or longer, 610 nm or longer, or 620 nm or longer, with an IQE sufficient to achieve desired display brightness levels. One technical solution to the foregoing technical problem is to implement LEDs (e.g., red LEDs) that operate with increased electric fields in their QWs. In some implementations, this technical solution can include modifying an indium (In) content of the QWs, as compared to prior implementation, and including barrier layers (e.g., barriers, quantum barriers, quantum barrier layers, etc.) between QWs of the LEDs, where at least some of the barriers contain aluminum (Al). One technical benefit of the foregoing technical solution is to facilitate producing III-Nitride LEDs that achieve light emission at wavelengths for red light emission, such as those noted above, with IQEs that provide increased brightness as compared to prior implementations.

In III-Nitride LEDs with an InGaN active regions or QW, an emission wavelength of light produced by an InGaN QW depends on its composition. In prior implementations, red light emission (e.g., for red LEDs) has been achieved by implementing QWs of red LEDs with a high indium content, e.g., on the order of 35% or greater, or 40% or greater. For purposes of this disclosure, percent content of a particular element of a composition can be referred to by including an indication of that element in brackets. For instance, the foregoing indium content can be described as [In] of 35% or greater, or 40% or greater. Also for purposes of this disclosure, compositions referred to herein are relative compositions of the group-III elements. For instance, for an aluminum-indium-gallium-nitride layer (AlInGaN) layer, a sum of respective composition contents of [Al], [In] and [Ga] are 100%.

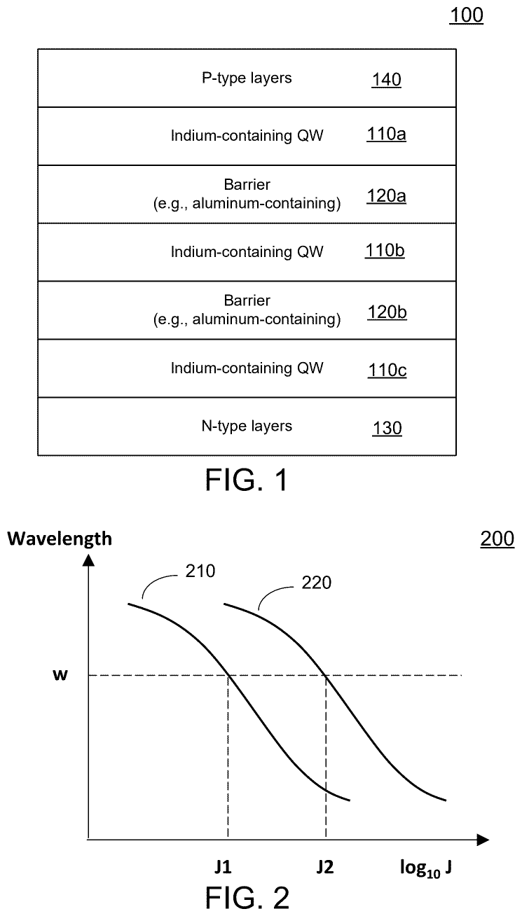

FIG. 1 is a diagram schematically illustrating an example light-emitting diode (LED 100) with aluminum-containing barriers. The LED 100 includes an indium-containing (In-containing) quantum well (QW) 110a, an In-containing QW 110b, and an In-containing QW 110c.

In the example of FIG. 1, the In-containing QW 110a and the In-containing QW 110b are separated by a barrier 120a, where the barrier 120a includes at least one aluminum-containing (Al-containing) layer. Also in the LED 100, the In-containing QW 110b and the In-containing QW 110c are separated by a barrier 120b, where the barrier 120b includes at least one Al-containing layer. In some implementations, the In-containing QWs can be indium-gallium-nitride (InGaN) QWs, and the Al-containing layers can be aluminum-gallium-nitride (AlGaN) layers. Generally, some implementations include barrier layers that have a high bandgap and cause a large polarization field across the light-emitting quantum well.

As shown in FIG. 1, the LED 100 also includes N-type semiconductor layers 130 and P-type semiconductor layers 140, which can include III-nitride semiconductor materials, such as gallium-nitride (GaN). In some implementations, the N-type semiconductor layers 130 and the P-type semiconductor layers 140 can include respective pluralities of layers, which can include doped and/or undoped layers. The particular arrangement of the N-type semiconductor layers 130 and the P-type semiconductor layers 140 will depend on the particular implementation.

In some implementations, the layers of the LED 100 shown in FIG. 1 can be grown using one or more epitaxial processes (epitaxial runs). The LED 100 of FIG. 1 is provided for purposes of illustration and by way of a general example of an implementation of an LED in accordance with the foregoing technical solution. Variations of such LEDs'structure, such as those described herein, are possible

FIG. 2 is a graph 200 illustrating a comparison of emission wavelength as a function of current density for an LED including aluminum-containing barriers with a prior LED implementation. That is, the graph 200 illustrates a comparison of two LEDs having different active region designs, where the active regions include QWs and corresponding barriers. In the example of FIG. 2, both of the LEDs illustrated have InGaN-containing wells with a same [In]. The LED illustrated by trace 210 is an LED in accordance with prior implementations, where the barriers of the LED of trace 210 are GaN barriers. The LED illustrated by trace 220 is an LED in accordance with the foregoing described technical solution. That is, the LED illustrated by trace 220 includes Al-containing barriers, such as one or more AlGaN barrier layers.

In FIG. 2, normalized current density is represented on the x-axis, e.g., as log₁₀ of current density J, and normalized wavelength is represented on the y-axis. As shown in FIG. 2, the wavelength-to-current relationship is shifted to a higher operating current density for the LED of trace 220. For instance, as illustrated in FIG. 2, a predetermined emission wavelength w is reached at a current density J1 for the LED of trace 210, and at current density of J2 for the LED of trace 220, where J2 is greater than J1. Accordingly, FIG. 2 illustrates that implementations in accordance with the technical solution described above, e.g., including Al-containing barriers between QWs, can facilitate achieving a longer emission wavelength, e.g., at a given operating current density, for LEDs with a same quantum well composition, e.g., a same [In].

For instance, in this example, based on experimental results, the predetermined wavelength w can be 620 nm, and both LEDs can have quantum wells with [In]=25%. Further, the LED represented by trace 210 can include GaN barriers, and emit at light with the wavelength w, e.g., 620 nm, at an operating current density J2=0.1 amperes-per-centimeter-squared (A/cm²). Further in this example, the LED corresponding with trace 220 can include Al-containing barriers, and emit light at the wavelength w, e.g., 620 nm, at an operating current density J2=10 A/cm2. Accordingly, the example of FIG. 2 demonstrates that LEDs in accordance with example implementations described herein can facilitate red light emission at higher current densities, which can achieve increased display brightness as compared with prior implementations.

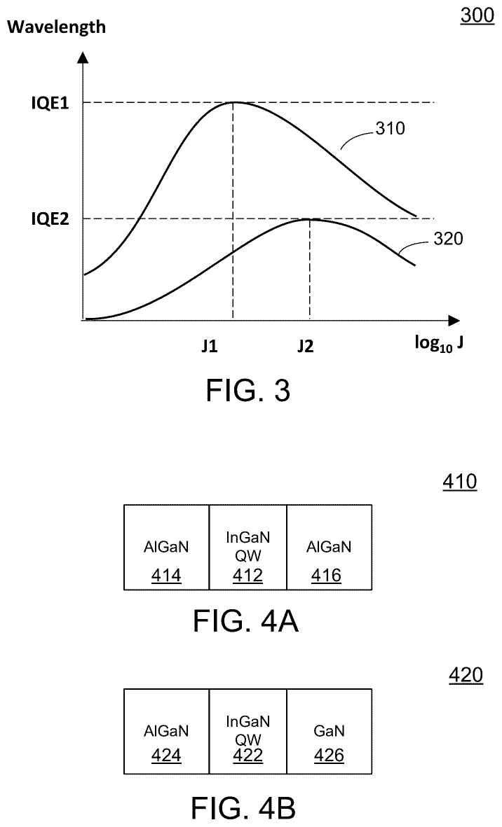

FIG. 3 is a graph 300 illustrating a comparison of internal quantum efficiency (IQE) for an LED including aluminum-containing barriers with a prior LED implementation. That is, FIG. 3 illustrates respective IQE curves of two LEDs having different active region designs, and emitting light at a same wavelength. For instance, IQE of a first LED is represented by trace 310 and IQE of a second LED is represented by trace 320. The LED represented by trace 310 is an example LED in accordance with implementations described herein. In this example, the LED of trace 310 includes Al-containing barriers and QWs that have a lower [In] as compared to the LED of trace 320. Further in this example, the LED of trace 310 includes GaN barriers and QWs that have a higher [In] as compared to the LED of trace 310. As shown in FIG. 3, the IQE of the LED of trace 310 is comparatively higher overall, and peaks at a value IQE1 at a comparatively lower current density J1. As also shown in FIG. 3, the LED of trace 320 has a comparatively lower IQE, which peaks at a value IQE2 at a comparatively higher current density J1. Accordingly, FIG. 3 illustrates that LEDs produced in accordance with the approaches described herein, e.g., LEDs with QWs having comparatively lower [In] than prior LED implementation can improve overall IQE.

In some implementations, LEDs produced in accordance with approaches and techniques described herein can operate with red light emission with a peak wavelength (lambda peak) of at least 600 nm (at least 605 nm, at least 610 nm, at least 615 nm, at least 620 nm, at least 625 nm, or at least 630 nm), where the red light is emitted by at least one In-containing QW with [In] below 30% (below 28%, below 25%, or below 22%). In some implementations, red light emission can be achieved at an operating current density of at least 1 A/cm² (at least 5 A/cm², or at least 10 A/cm²). In some implementations, IQE at such current densities can be at least 10% (at 15%, at least 20%, at least 25%, at least 30%, at least 35%, at least 40%, at least 50%, or at least 60%). In some implementations. a peak operating current density (e.g., a current density at which a peak IQE and/or a peak external quantum efficiency (EQE) occurs) can be at least 1 A/cm² (at least 5 A/cm², or at least 10 A/cm²). In some implementations, red light emission can also be characterized by a dominant wavelength (lambda_dom) of at least 590 nm (at least 595 nm, at least 600 nm, at least 605 nm, at least 610 nm, at least 615 nm, or at least 620 nm).

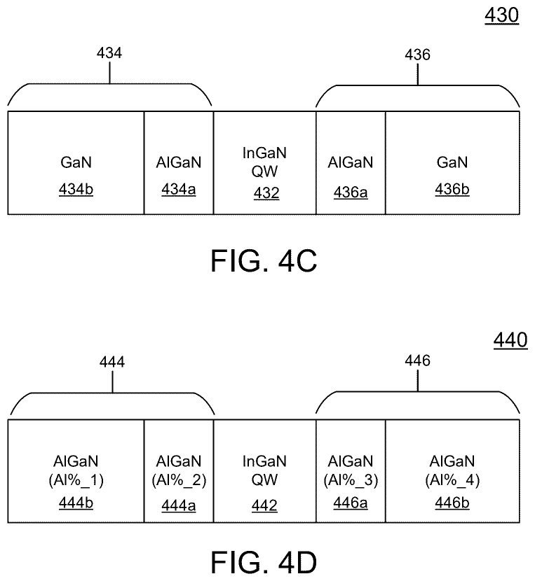

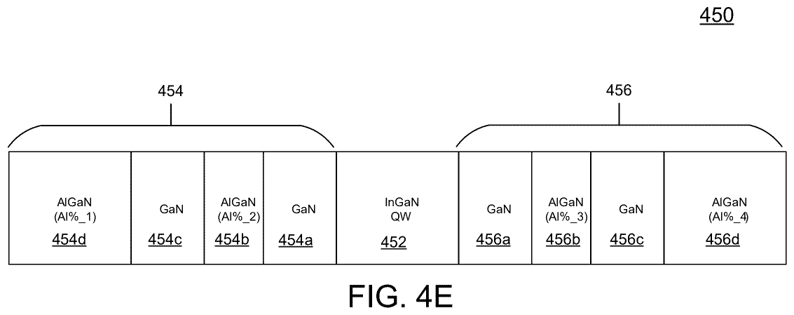

FIGS. 4A to 4E are diagrams schematically illustrating example active region periods for various LEDs. Specifically, FIGS. 4A to 4E schematically illustrate epitaxial structures for active regions of LEDs in accordance with the approaches described herein. In each of the examples of FIGS. 4A to 4E, a single period of a respective multiple QW (MQW) active region is shown. In general, the examples FIGS. 4A to 4E are characterized by the presence of Al in at least one of the respective barriers separating the QWs of the MQWs.

FIG. 4A illustrates a MQW period 410 that includes an InGaN QW 412 that is disposed between an AlGaN barrier 414 and an AlGaN barrier 416. FIG. 4B illustrates a MQW period 420 that includes an InGaN QW 422 that is disposed between an AlGaN barrier 424 and a GaN barrier 426.

FIGS. 4C to 4E illustrate respective MQW periods that include composite barriers. For instance, FIG. 4C illustrates a MQW period 430 that includes an InGaN QW 432 that is disposed between a composite barrier 434 and a composite barrier 436. The composite barrier 434 includes an AlGaN interlayer 434a that is in contact with the InGaN QW 432, and GaN barrier 434b that is in contact with the AlGaN interlayer 434a. The composite barrier 436 includes a AlGaN interlayer 436a that is in contact with the InGaN QW 432, and a GaN barrier 436b that is in contact with the AlGaN interlayer 436a.

FIG. 4D illustrates a MQW period 440 that includes an InGaN QW 442 that is disposed between a composite barrier 444 and a composite barrier 446. The composite barrier 444 includes an AlGaN spacer 444a that is in contact with the InGaN QW 442, and AlGaN barrier 444b that is contact with the AlGaN spacer 444a. The composite barrier 446 includes a AlGaN spacer 446a that is in contact with the InGaN QW 442, and a AlGaN barrier 446b that is in contact with the AlGaN spacer 446a. In the example, of FIG. 4D, the AlGaN spacer 444a has [Al] of Al %_2, the AlGaN barrier 444b had [Al] of Al %_1, the AlGaN spacer 446a has [Al] of Al %_3, and the AlGaN barrier 446b has [Al] of Al %_4. These specific [Al] of Al %_1, Al %_2, Al %_3 and Al %_4, as used herein, can vary depending on the particular implementation. Examples of values and relationships for these aluminum concentrations are discussed below.

FIG. 4E illustrates a MQW period 450 that includes an InGaN QW 452 that is disposed between a composite barrier 454 and a composite barrier 456. The composite barrier 454 includes a GaN spacer 454a that is in contact with the InGaN QW 452, an AlGaN spacer 454b (AlGaN interlayer) that is in contact with the GaN spacer 454a, a GaN spacer 454c that is contact with the AlGaN spacer 454b, and an AlGaN barrier 454d that is in contact with the GaN spacer 454c. The composite barrier 456 includes a GaN spacer 456a that is in contact with the InGaN QW 452, an AlGaN spacer 456b that is in contact with the GaN spacer 456a, a GaN spacer 456c that is contact with the AlGaN spacer 456b, and an AlGaN barrier 456d that is in contact with the GaN spacer 456c. In the example, of FIG. 4E, the AlGaN spacer 454b has [Al] of Al %_2, the AlGaN barrier 454d has [Al] of Al %_1, the AlGaN spacer 456b has [Al] of Al %_3, and the AlGaN barrier 456d has [Al] of Al %_4.

In some implementations, such as the examples of FIGS. 4A to 4E, by configuring material composition (e.g., [Al] content of various Al-containing barrier and spacer layers of corresponding active regions), it is possible to engineer polarization fields that are applied across respective QWs during electrical operation and, as a result, achieve variations in emission wavelength of emitted light. For instance, for a given composition of a quantum well, a corresponding emission wavelength can be increased using such approaches.

In some implementations, variations of the structures of FIGS. 4A to 4E can be used to implement LEDs, e.g., LEDs of pixels of a display panel. For instance, an AlGaN layer (barrier and/or spacer) can be included on only one side of a respective QW, such as in the example of FIG. 4B. In some implementations, such as in the example of FIG. 4E, one or more of the GaN spacers can be omitted. For instance, in the example of FIG. 4E, GaN spacers may be present only in some of the locations shown in FIG. 4E, e.g., only between the AlGaN barriers 454d and 456d and, respectively, the AlGaN spacers (interlayers) 454b and 456b, or only between the AlGaN spacers (interlayers) 454b and 456b and the InGaN QW 452.

While periodic structures are illustrated and described herein, aperiodic structures can also be implemented using the described approaches. For instance, an LED can have a plurality of QWs with corresponding AlGaN-containing barriers, where respective compositions and/or respective thicknesses of the QWs and barrier layers vary along an epitaxial growth direction of the LED layers. In some implementations, layers of an LED can include graded layers, where respective contents of various atoms, e.g., [Ga], [Al], and/or [In], continuously vary, respectively, across the layers. In some implementations, alternatives to AlGaN layers can be used. For instance, in some implementations Al-containing layers such as AlInGaN or AlInN can be used for implementing barriers (quantum barriers).

In some implementations, [Al] for AlGaN layers, e.g., whether barriers or spacers in the examples of FIGS. 4A to 4E, can be in a range of 1%-10% (in a range of 3%-15%, in a range of 5%-20%, in a range of 10%-30%, in a range of 20-50%, in a range of 25-70%, or in a range of 30-100%). In some examples, AlGaN interlayers can have [Al] that is greater than an [Al] for AlGaN barriers. For instance, with reference to FIG. 4D, Al %_2 and Al %_3 can be greater than Al %_1 and Al %_4).

In some implementations, light-emitting QWs can include respective layers of InGaN, as in the examples of FIGS. 4A to 4E. In some implementations, AlInGaN, or other In-containing III-nitride compounds can be used to implement QWs. In some implementations, a QW can include AlInGaN with [Al] less than 5% (less than 2%, less than 1%, or less than 0.1%) and/or more than 0.01% (or more than 0.1%). In some implementations, a local composition of a QW may not be uniform along an epitaxial growth direction. In such implementations, composition of the QW can be defined as respective averages of material content (concentration) across the QW thickness, e.g., along the epitaxial growth direction.

In some implementations, the approaches and techniques described herein can be used to produce so-called deep-red LEDs that have a moderate [In]. For instance, such a deep-red LED can have a plurality of In-containing QWs with [In] less than 35%, but emit light with an emission wavelength of at least 660 nm at an operating current density of J=1 A/cm².

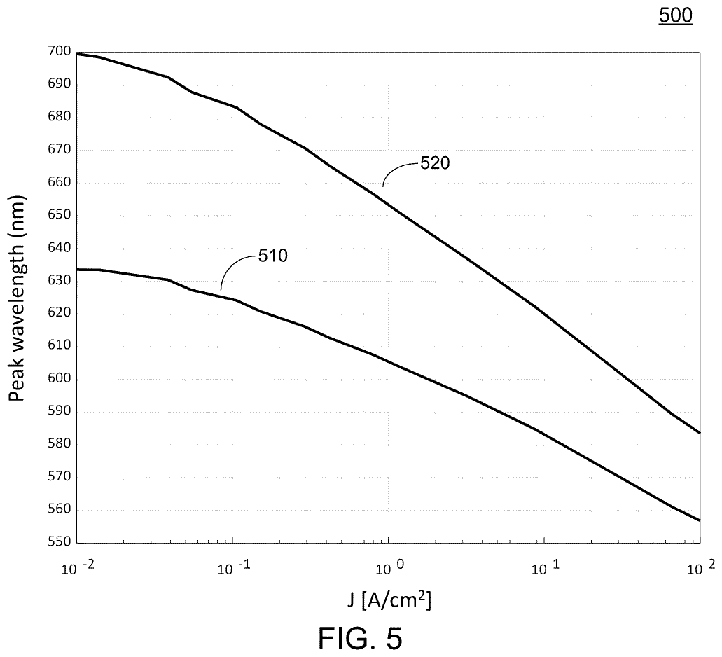

FIG. 5 is a graph 500 illustrating experimental results comparing peak emission wavelength as a function of operating current density for LEDs with aluminum-containing barriers with different aluminum percentage contents. Trace 510 represents a first LED and trace 520 represents a second LED. The LED of trace 510 and the LED of trace 520 both have a same nominal [In] of 25%. The LED of trace 510 has a first AlGaN-based multi-layer barrier configuration, with the LED of trace 520 has a second AlGaN-based multi-layer barrier configuration. In this example, [Al] of a layer of the barriers for the LED of trace 520 is greater than [Al] for the corresponding layer of the barriers of the LED of trace 510.

As shown in FIG. 5, a result of different [Al] in the two LEDs is that light emission wavelength, for a given operating current density J, is shifted up by tens of nanometers for the LED of trace 520 compared with the LED of trace 510, e.g., shifted up by about 50 nm at J=1 A/cm². In this example, the LED of trace 520 demonstrates the following operational characteristics: at J=0.1 A/cm², wavelength is greater than 680 nm; at J=1 A/cm², wavelength is greater than 650 nm; at J=10 A/cm², wavelength is greater than 620 nm; and at J =30A/cm², wavelength is greater than 600 nm.

While example implementations described herein generally reference AlGaN barriers, in some implementations, other materials and/or elements can be used to implement such barriers, e.g., to increase the polarization field across the light-emitting quantum wells, such as in comparison to GaN barriers. For instance, III-nitride layers (e.g., barriers) can contain one or more of gallium (Ga), aluminum (Al), scandium (Sc), and/or boron (B). B-containing and Sc-containing III-nitride layers (such as BGaN, ScGaN, BAlN, ScAlN, BAlGaN, ScAlGaN, BAlInGaN, ScAlInGaN) can provide a high bandgap and large polarization fields and, accordingly, can be used for barrier materials. In some implementations, a particular composition can be selected to achieve a desired strain state. For instance, a ScAlN barrier can be configured to be lattice matched to GaN, or lattice matched to a material of a corresponding QW. For each of the elements Al, B, Sc, a composition in a barrier layer may be in a range of 5-95% (in a range of 10-90%, or in a range of 10-50%). In some implementations, a composition of a barrier layer can be selected to have a wurtzite crystal lattice.

In some implementations, a moderate amount of In (e.g., less than 10%, less than 3%, or less than 1%) may be added to a barrier material, which can improve its quality.

In some implementations, barrier layers can be characterized by their band gap and/or by a polarization field that they induce across a QW, rather than by a material composition. Using approaches described herein, and incorporating materials such as Al, B, Sc in a barrier material, a desired polarization field can be achieved.

For instance, in some implementations, a barrier includes a layer with a band gap of at least 4eV (at least 4.5eV, or at least 5eV).

In some examples, a barrier can be configured to facilitate a polarization field across a quantum well than is at least 1.5 MV/cm (at least 2 MV/cm, at least 2.5 MV/cm, or at least 3 MV/cm).

In some implementations, a polarization-filed-induced energy drop across a QW (computed as the product of the polarization field and the QW thickness) is at least 300 meV (at least, at least 500 meV, at least 700 meV, or at least 1000 meV).

In some examples, an LED can be grown on a semiconductor template (e.g., a GaN template or an InGaN template). Layers of barriers of the LED can be pseudo-morphic with the semiconductor template. Quantum wells of the LED can be pseudo-morphic with the semiconductor template.

In some implementations, LEDs as described herein can be included in a monolithically-integrated III-nitride display, wherein pixels of the display respectively include at least three III-Nitride LEDs having three colors (e.g., red, green, and blue) that are grown on a same epitaxial substrate. In some implementations, the LEDs can be grown in one or several epitaxial runs. The red LEDs can have [In] that is less than or equal to 30%. In some implementations, the approaches described herein can be used for green LEDs and/or blue LEDs. In some implementations, a green LED can have a green light emission wavelength of at least 520 nm (at least 530 nm, or at least 540 nm), where the green light is emitted with at least one quantum well having [In] of less than 23% (less than 20%, less than 18%, or less than 15%). In some implementations, such green light emission can be achieved at a current density of at least 1 A/cm² (at least 5 A/cm², or at least 10 A/cm²).

In some implementations, LEDs produced using the approaches and techniques described herein can be included in high-brightness displays. Such high-brightness displays can be microLED micro-displays emitting light with a brightness of at least 0.1 million nits (at least 0.5 million nits, at least 1 million nits, at least 2 million nits, or at least 5 million nits). Such displays can have a pixel pitch of less than 10 μm (less than 5 μm, or less than 3 μm). In some implementations, micro-LEDs can have lateral dimensions less than 10 μm (less than 5 μm, less than 3 μm, or less than 1 μm).

In some implementations, a display (display panel) can include monolithically-integrated red InGaN LEDs (red microLEDs), green InGaN LEDs (red microLEDs), and blue InGaN LEDs (blue microLEDs). Pixels of such a display can respectively have a red microLED, a green microLED, and a blue micro LED, acting as sub-pixels of the pixel. In some implementations, red LEDs (e.g., red microLEDs) can have multiple quantum wells with [In] less than 30% (less than 28%, less than 25%, or less than 23%) and one or more Al-containing barriers disposed respectively between the quantum wells. Such red LEDs can emit red light at a wavelength higher than a predetermined red wavelength (e.g., at least 600 nm, at least 605 nm, at least 610 nm, at least 615 nm, at least 620 nm, at least 625 nm, or at least 630 nm) when driven at an operating current density Jred that is greater than 1 A/cm² (greater than 2 A/cm², greater than 5 A/cm², or greater than 10 A/cm²). In some implementations, a display panel including LEDs as described herein can be configured to emit D65 white light, with the red LEDs driven at current density Jred, such that brightness of the D65 white point is at least 1 million nits. Further, such a display may be capable of displaying a gamut whose area is at least the sRGB gamut.

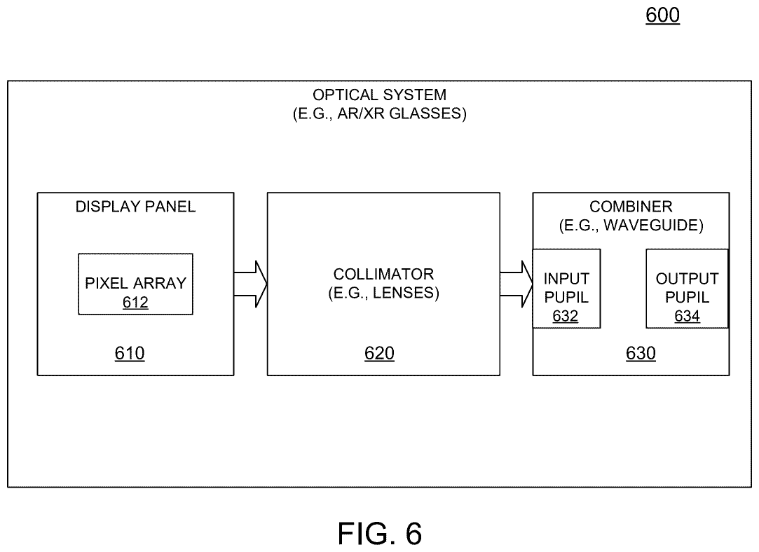

FIG. 6 is a diagram schematically illustrating an example optical system 600. In some implementations, the optical system 600 can be included in a wearable device, such an AR/XR headset, AR/XR glasses, and so forth. In the example of FIG. 6, the optical system 600 includes a display panel 610 (e.g., a microLED display panel), a collimator 620, and a combiner 630. In this example, the display panel 610 can be an emissive display panel including LEDs such as those described herein. The LEDs of the display panel can implement pixels of a pixel array 612

The collimator 620 can include a set of lenses that collimates light emission received from the pixel array 612 of the display panel 610. The combiner 630 can include a waveguide (e.g., a diffractive waveguide, and/or a reflective waveguide). As shown in FIG. 6, the combiner 630 includes an input pupil 632 (entrance pupil) and an output pupil 634 (exit pupil). The input pupil 632 can receive light from the collimator, and the output pupil 634 can emit light towards an eye of a viewer of the optical system 600. The optical system 600 can modify (e.g., filter) a light spectrum emitted by the display panel 610 (e.g., due to different optical efficiency/transmission of the optical system as a function of wavelength). Accordingly, in some examples, chromaticity of light (such as white light near the D65 chromaticity) can be achieved at an output of the optical system (e.g., from the output pupil 634), rather than from the display panel 610 itself. In some cases, the chromaticity can be sufficiently close to the D65 chromaticity. Such a chromaticity difference can be quantified by a color distance, e.g., Du‘v’, between chromaticity of the emitted light and the D65 chromaticity. In some implementations, Du‘v’ is less than 5e-2 (less than 1e-2, less than 5e-3. or less than 1e-3). In some implementations, a high-brightness display, e.g., a microLED display, can facilitate a high brightness delivered to an eye of the viewer of the optical system. For instance, the optical system 600 of this example can deliver light with a brightness of at least 500 nits (at least 1000 nits, at least 2000 nits, or at least 5000 nits).

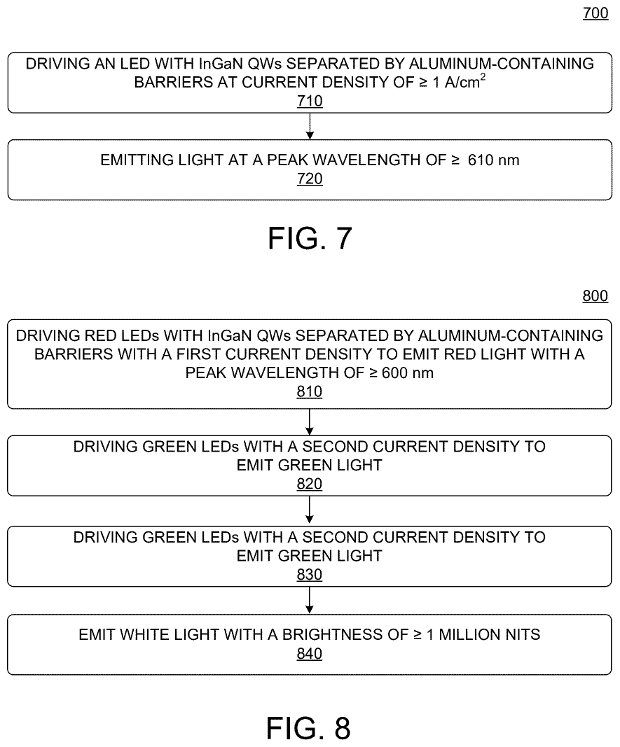

FIG. 7 is a flowchart illustrating an example method 700 of operating an LED, e.g., a red microLED. In some implementations, the method 700 can be implemented using LEDs as described herein to achieve light emission with corresponding characteristics of those LEDs. For instance, at operation 710, the method 700 includes driving an LED with a plurality InGaN QWs that are separated by respective barriers, including at least one Al-containing barrier. At operation 710, the method 700 includes driving the LED with an operating current density of greater than or equal to 1 A/cm². At operation 720, the method 700 includes emitting, from the plurality of InGaN QWs, light (red light) at a peak wavelength of greater than or equal to 610 nm.

FIG. 8 is a flowchart illustrating an example method 800 of operating a display, such as the displays described herein (e.g., the display panel 610 and/or the optical system 600). In some implementations, as with the method 700, the method 800 can be implemented using LEDs as described herein to achieve light emission with corresponding characteristics of those LEDs. For instance, at operation 810, the method 800 includes driving red LEDs, e.g., of respective pixels of a display. In this example, the red LEDs each include a plurality of InGaN QWs that are separated by respective barriers, including at least one Al-containing barrier. At operation 810, the QWs of the red LEDs are driven with a first current density and emit red light with a peak wavelength of greater than or equal to 620 nm. At operation 820, the method 800 includes driving green LEDs of the pixels with a second current density, such that QWs of the green LEDs emit green light. At operation 830, the method 800 includes driving blue LEDs of the pixels with a third current density, such that QWs of the blue LEDs emit blue light. At operation 840, as result of the red light, green light and blue light respectively emitted at operations 810, 820 and 830, the method 800 includes emitting white light with brightness of greater than or equal to 1 million nits.

In some implementations, the white light at operation 840 can have a D65 chromaticity. In some implementations, the white light of operation 840 can be filtered by an optical system (e.g., by the combiner 630 of the optical system 600). Filtered light output by the optical system can have a brightness that is greater than or equal to 1000 nits. In some implementations, the first current density of operation 810 can be greater than or equal to 2 A/cm². In some implementations, the red LEDs, the green LEDs and the blue LEDs can be monolithically grown on a same growth substrate.

In a general aspect, a light-emitting diode (LED) includes a plurality of indium-gallium-nitride (InGaN) quantum wells (QWs). The plurality of InGaN QWs include respective light-emitting indium-containing layers having an indium concentration of less than 30%. The LED further includes a plurality of quantum barriers respectively disposed between the plurality of InGaN QWs. The plurality of quantum barriers include respective aluminum-containing layers. The LED, during electrical operation, is configured to emit light at a peak wavelength greater than 610 nanometers (nm) at a current density greater than or equal to 1 amp-per-centimeter-squared (A/cm2).

Implementations can include one or more of the following features, or aspects, alone or in combination. For example, the respective aluminum-containing layers can have an aluminum concentration of greater than five percent.

The plurality of InGaN QWs can have respective thicknesses in range of 2 nanometers (nm) to 5 nm.

The plurality of InGaN QWs, during electrical operation of the LED, can emit light with an internal quantum efficiency of greater than 10% at the current density of 1 A/cm2.

The plurality of InGaN QWs can include five InGaN QWs. The respective aluminum-containing layers can include respective aluminum-gallium-nitride (AlGaN) layers.

The respective aluminum-containing layers can have respective thicknesses greater than or equal to 1 nm.

During electrical operation, the LED can operate with a peak internal quantum efficiency (IQE) of greater than or equal to 10%. The peak internal quantum efficiency can occur at an operating current density of greater than or equal to 5 A/cm2.

The plurality of quantum barriers can include respective pluralities of aluminum-containing layers.

In another general aspect, a display includes a plurality of pixels. A pixel of the plurality of pixels includes a red light-emitting diode (LED) having a plurality of indium-gallium-nitride-containing (InGaN-containing) red quantum wells (QWs) that are respectively separated by aluminum-containing quantum barriers. The display further includes a green LED having a plurality of InGaN-containing green QWs, and a blue LED having a plurality of InGaN-containing blue QWs. The display is configured, during electrical operation, to emit white light with a brightness greater than 1 million nits, with the red LED having a peak wavelength of greater than or equal to 600 nanometers (nm).

Implementations can include one or more of the following features, or aspects, alone or in combination. For example, the plurality of InGaN-containing red QWs can have respective indium concentrations of less than 30%.

The white light can have a D65 chromaticity.

The display can include an optical system. The plurality of pixels can be optically coupled with the optical system. The optical system can be configured to: receive light emission from the plurality of pixels, and filter the light emission to produce a white light emission.

The white light emission can have a brightness of greater than or equal to 1000 nits.

The red LED, the green LED, and the blue LED can be monolithically formed on a single growth substrate.

The aluminum-containing quantum barriers can respectively include a layer having an aluminum concentration of greater than or equal to 10%.

In another general aspect, a method of operating a display includes emitting white light having a brightness greater than or equal to one-million nits. The method includes respectively driving a plurality of red light-emitting diodes (LEDs) of pixels of the display with a first current density to emit red light with a peak wavelength of greater than or equal to 600 nanometers (nm). The plurality of red LEDs including respective pluralities of indium-gallium-nitride-containing (InGaN-containing) red quantum wells (QWs) that are separated by quantum barriers containing aluminum,. The method further includes respectively driving a plurality of green LEDs of the pixels with a second current density to emit green light, and respectively driving a plurality of blue LEDs of the pixels with a third current density to emit blue light.

Implementations can include one or more of the following features, or aspects, alone or in combination. For example, the white light can have a D65 chromaticity.

The method can include filtering the white light with an optical system. The optical system can emit filtered white light with a brightness of greater than or equal to 1000 nits.

The first current density can be greater than or equal to 2 amperes-per-centimeter-squared (A/cm2).

The plurality of red LEDs, the plurality of green LEDs, and the plurality of blue LEDs can be monolithically disposed on a same growth substrate.

It will be understood, for purposes of this disclosure, that when an element, such as a layer, a region, or a substrate, is referred to as being on, disposed on, disposed in, connected to, electrically connected to, coupled to, or electrically coupled to another element, it may be directly on, connected or coupled to the other element, or one or more intervening elements may be present. In contrast, when an element is referred to as being directly on, directly disposed on, directly disposed in, directly connected to or directly coupled to another element or layer, there are no intervening elements or layers present. Although the terms directly on, direct in, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to, vertically adjacent to, or horizontally adjacent to.

Some implementations may be implemented using various semiconductor processing and/or packaging techniques. Some implementations may be implemented using various types of semiconductor processing techniques, such as epitaxial growth processes, associated with semiconductor substrates and materials including, but not limited to, for example, silicon (Si), gallium arsenide (GaAs), gallium nitride (GaN), silicon carbide (SiC), and/or so forth.

While certain features of various example implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A light-emitting diode (LED) comprising:
a plurality of indium-gallium-nitride (InGaN) quantum wells (QWs) including respective light-emitting indium-containing layers having an indium concentration of less than 30%; and
a plurality of quantum barriers respectively disposed between the plurality of InGaN QWs, the plurality of quantum barriers including respective aluminum-containing layers,
the LED, during electrical operation, being configured to emit light at a peak wavelength greater than 610 nanometers (nm) at a current density greater than or equal to 1 amp-per-centimeter-squared (A/cm²).

2. The LED of claim 1, wherein the respective aluminum-containing layers have an aluminum concentration of greater than five percent.

3. The LED of claim 1, wherein the plurality of InGaN QWs have respective thicknesses in range of 2 nanometers (nm) to 5 nm.

4. The LED of claim 1, wherein the plurality of InGaN QWs, during electrical operation of the LED, emit light with an internal quantum efficiency of greater than 10% at the current density of 1 A/cm2.

5. The LED of claim 1, wherein:
the plurality of InGaN QWs includes five InGaN QWs; and
the respective aluminum-containing layers include respective aluminum-gallium-nitride (AlGaN) layers.

6. The LED of claim 1, wherein the respective aluminum-containing layers have respective thicknesses greater than or equal to 1 nm.

7. The LED of claim 1, wherein, during electrical operation, the LED operates with a peak internal quantum efficiency (IQE) of greater than or equal to 10%.

8. The LED of claim 7, wherein the peak internal quantum efficiency occurs at an operating current density of greater than or equal to 5A/cm2.

9. The LED of claim 1, wherein the plurality of quantum barriers include respective pluralities of aluminum-containing layers.

10. A display comprising:
a plurality of pixels, a pixel of the plurality of pixels comprising:
a red light-emitting diode (LED) having a plurality of indium-gallium-nitride-containing (InGaN-containing) red quantum wells (QWs) that are respectively separated by aluminum-containing quantum barriers;
a green LED having a plurality of InGaN-containing green QWs; and
a blue LED having a plurality of InGaN-containing blue QWs,
the display being configured, during electrical operation, to emit white light with a brightness greater than 1 million nits, with the red LED having a peak wavelength of greater than or equal to 600 nanometers (nm).

11. The display of claim 10, wherein the plurality of InGaN-containing red QWs have respective indium concentrations of less than 30%.

12. The display of claim 10, wherein the white light has a D65 chromaticity.

13. The display of claim 10, further comprising an optical system, the plurality of pixels being optically coupled with the optical system,
the optical system being configured to:
receive light emission from the plurality of pixels; and
filter the light emission to produce a white light emission.

14. The display of claim 13, wherein the white light emission has a brightness of greater than or equal to 1000 nits.

15. The display of claim 10, wherein the red LED, the green LED, and the blue LED are monolithically formed on a single growth substrate.

16. The display of claim 10, wherein the aluminum-containing quantum barriers respectively include a layer having an aluminum concentration of greater than or equal to 10%.

17. A method of operating a display, comprising:
emitting white light having a brightness greater than or equal to one-million nits including:
respectively driving a plurality of red light-emitting diodes (LEDs) of pixels of the display with a first current density to emit red light with a peak wavelength of greater than or equal to 600 nanometers (nm), the plurality of red LEDs including respective pluralities of indium-gallium-nitride-containing (InGaN-containing) red quantum wells (QWs) that are separated by quantum barriers containing aluminum,
respectively driving a plurality of green LEDs of the pixels with a second current density to emit green light; and
respectively driving a plurality of blue LEDs of the pixels with a third current density to emit blue light.

18. The method of claim 17, wherein the white light has a D65 chromaticity.

19. The method of claim 17, further comprising filtering the white light with an optical system.

20. The method of claim 19, wherein the optical system emits filtered white light with a brightness of greater than or equal to 1000 nits.

21. The method of claim 17, wherein the first current density is greater than or equal to 2 amperes-per-centimeter-squared (A/cm²).

22. The method of claim 17, wherein the plurality of red LEDs, the plurality of green LEDs, and the plurality of blue LEDs are monolithically disposed on a same growth substrate.
